(19) United States
(12) Patent Application Publication
(10) Pub. No.: US 2016/0262289 A1
(43) Pub. Date: Sep. 8, 2016

(54) HEAT SPREADER-BASED HEAT SINK MODULE

(71) Applicant: TAI-SOL ELECTRONICS CO., LTD., TAIPEI CITY (TW)

(72) Inventors: Yun-Yeu YEH, TAIPEI CITY (TW); Chun-Huang CHOU, TAIPEI CITY (TW); Chih-Wei CHEN, TAIPEI CITY (TW)

(21) Appl. No.: 14/698,340

(22) Filed: Apr. 28, 2015

(30) Foreign Application Priority Data
Mar. 2, 2015 (TW) 104106490

(51) Int. Cl. H05K 7/20; F28F 13/06

(52) U.S. Cl. CPC H05K 7/20418; F28F 13/06

(57) ABSTRACT

A heat spreader-based heat sink module includes a heat spreader; a radiation fin set consisting of middle radiation fins on the middle and lateral radiation fins at two opposite lateral sides, the lateral radiation fins having end edges thereof defining with the middle radiation fins multiple installation spaces, the installation spaces being disposed at the two opposite lateral sides of the radiation fin set, each middle radiation fin defining a bearing portion between one respective pair of installation spaces; one or multiple retaining frames each including a holding-down segment located on the middle and pressed on one respective bearing portion of each middle radiation fin and two mounting segments respectively extended from two opposite ends of the holding-down segment and respectively positioned in one respective installation space; and multiple screw respectively mounted in the mounting segments of the one or multiple retaining frames.

### BACKGROUND OF THE INVENTION

1. Field of the Invention

The present invention relates to cooling technology and more particularly, to a heat spreader-based heat sink module that combines a heat spreader and a radiation fin set for heat dissipation.

2. Description of the Related Art

Taiwan Patent TW M336672 discloses a utility model of heat sink module. This design discloses a heat spreader and heat sink combination. The technical feature of this prior art design is to affix a heat spreader to a holder frame, and then to fasten the holder frame to a plate member at a bottom side of a radiator, thereby joining the heat spreader and the radiator for quick dissipation of heat. According to this prior art design, the holder frame is used to secure the heat spreader to the radiator. In some conditions, the heat spreader and the radiator can be joined together without the holder frame.

Further, a radiator can be made by hooking up multiple radiation fins together. Taiwan Patent TW M349482 discloses a cooling design entitled “Lapped type heat spreader and cooling device using same”. According to this prior art design, the radiator of the heat sink is made by hooking up multiple radiation fins together. However, this prior art design needs to use a panel frame for holding the first and second heat spreaders. Further, this prior art design simply enables the heat sink to be bonded to the first and second heat spreaders without providing any holding-down means for holding down the heat sink on the first and second heat spreaders positively in position.

### SUMMARY OF THE INVENTION

The present invention has been accomplished under the circumstances in view. It is the main object of the present invention to provide a heat spreader-based heat sink module that eliminates the use of a holder frame or panel frame to hold the heat spreader and employs a holding down technique to hold down radiation fin set on the heat spreader, providing the characteristics of simple structure and excellent heat dissipation performance.

To achieve this and other objects of the present invention, a heat spreader heat spreader-based heat sink module comprises a heat spreader, a radiation fin set, at least one retaining frame, and at least two screws. The radiation fin set consists of a plurality of elongated radiation fins. Each radiation fin comprises an extension strip extended from each of two opposite long sides thereof The radiation fins are arranged in parallel, and joined to one another and spaced from one another at a predetermined distance by means of the extension strips thereof The extension strips at one same long side of the radiation fins of the radiation fin set constitute a flat bottom surface that is bonded with a top surface of the heat spreader. The radiation fins located on a middle part of the radiation fin set are defined as middle radiation fins. The other radiation fins located on two opposite lateral sides of the radiation fin set are defined as lateral radiation fins. The lateral radiation fins are relatively shorter than the middle radiation fins. The lateral radiation fins have end edges thereof defining with the middle radiation fins at least two installation spaces. The at least two installation spaces are disposed at the two opposite lateral sides of the radiation fin set. Further, each end of each of the middle radiation fins that protrudes over the respective one ends of the lateral radiation fins defines a bearing portion between one respective pair of the installation spaces at one of two opposite sides of the radiation fin set. The at least one retaining frame is made in the shape of an elongated frame bar. Each retaining frame comprises a holding-down segment on the middle, and two mounting segments respectively extended from two opposite ends of the holding-down segment vertically downwards and then horizontally outwards. The holding-down segment of each retaining frame is pressed on a top surface of one respective bearing portion of each middle radiation fin. The mounting segments of the at least one retaining frame are respectively positioned in the installation spaces. The at least two screws are respectively mounted in the mounting segments of the at least one retaining frame. Further, the heat spreader is kept beyond the installation spaces.

Thus, the invention eliminates the use of a holder frame or panel frame as seen in the prior art designs, and uses a holding down technique to hold down the radiation fin set on the heat spreader, providing the characteristics of simple structure and excellent heat dissipation performance.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is an oblique top elevational view of a heat spreader-based heat sink module in accordance with a first embodiment of the present invention.

FIG. 2 is an exploded view of the heat spreader-based heat sink module in accordance with the first embodiment of the present invention.

FIG. 3 is an enlarged view of a part of FIG. 2, illustrating the connection of the radiation fins.

FIG. 4 is a bottom view of the heat spreader-based heat sink module in accordance with the first embodiment of the present invention.

FIG. 5 is a side view of the heat spreader-based heat sink module in accordance with the first embodiment of the present invention.

FIG. 6 is a schematic applied view of the present invention before installation of the heat spreader-based heat sink module in a heat source.

FIG. 7 is an oblique top elevational view of a heat spreader-based heat sink module in accordance with a second embodiment of the present invention.

FIG. 8 is a bottom view of the heat spreader-based heat sink module in accordance with the second embodiment of the present invention.

FIG. 9 is an oblique top elevational view of a heat spreader-based heat sink module in accordance with a third embodiment of the present invention.

FIG. 10 is a bottom view of the heat spreader-based heat sink module in accordance with the third embodiment of the present invention.

FIG. 11 is an oblique top elevational view of a heat spreader-based heat sink module in accordance with a fourth embodiment of the present invention.

FIG. 12 is a bottom view of the heat spreader-based heat sink module in accordance with the fourth embodiment of the present invention.

FIG. 13 is an oblique top elevational view of a heat spreader-based heat sink module in accordance with a fifth embodiment of the present invention.

FIG. 14 is a bottom view of the heat spreader-based heat sink module in accordance with the fifth embodiment of the present invention.

### DETAILED DESCRIPTION OF THE INVENTION

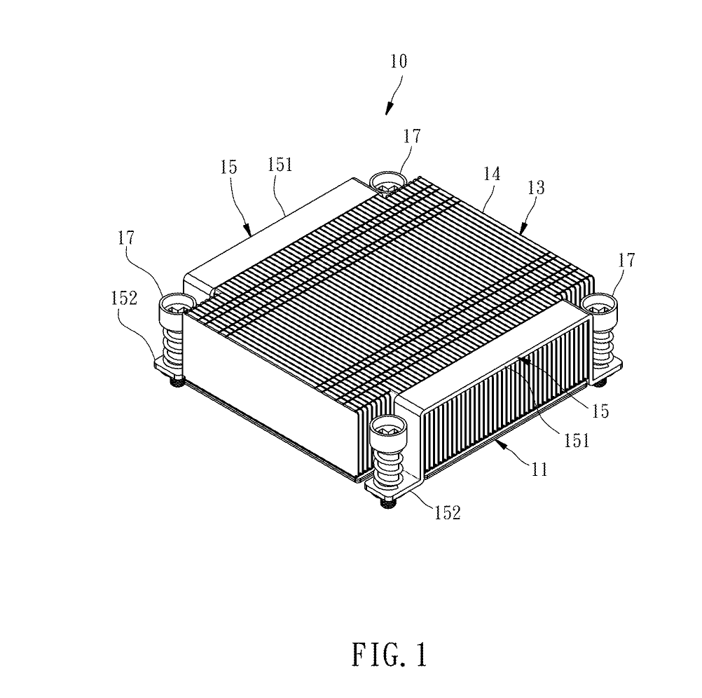

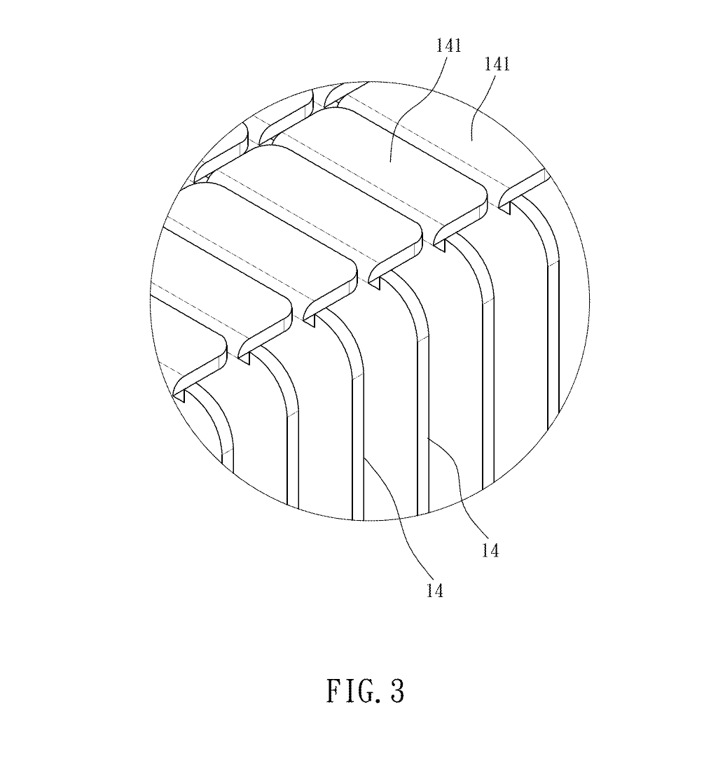

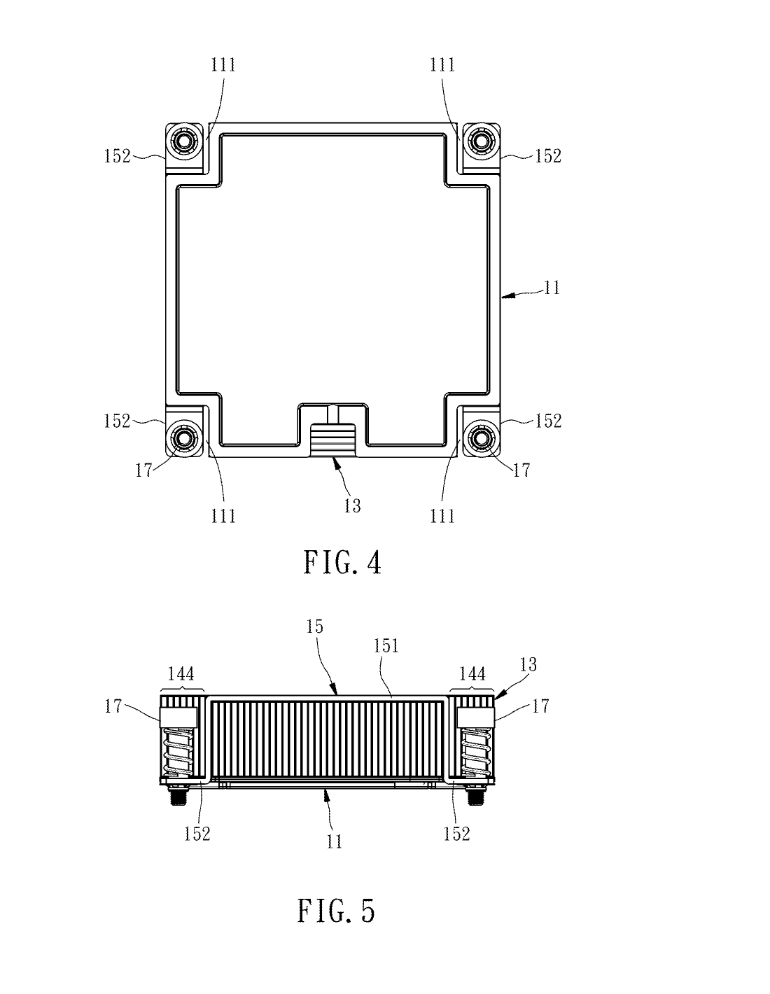

Referring to FIGS. 1-6, a heat spreader-based heat sink module in accordance with a first embodiment of the present invention is shown. The heat spreader-based heat sink module 10 comprises a heat spreader 11, a radiation fin set 13, two retaining frames 15, and four screws 17.

The radiation fin set 13 consists of a plurality of elongated radiation fins 14. Each radiation fin 14 comprises an extension strip 141 extended from each of two opposite long sides thereof. These radiation fins 14 are arranged in parallel, and joined to one another and spaced from one another at a predetermined distance by means of the extension strips 141. The extension strips 141 at one same long side of the radiation fins 14 of the radiation fin set 13 constitute a flat bottom surface of the radiation fin set 13 and directly bonded to a top surface of the heat spreader 11. The technique of joining the radiation fins 14 is of the known art and not within the scope of the present invention, therefore no further detailed description in this regard will be necessary.

The main features of this first embodiment of the present invention are outlined hereinafter.

Define those radiation fins 14 on the middle part as middle radiation fins 142, and the other radiation fins on the two opposite lateral sides as lateral radiation fins 144. These lateral radiation fins 144 are relatively shorter than the middle radiation fins 142. The middle radiation fins 142 have two opposite ends thereof respectively protruding over respective two opposite ends of the lateral radiation fins 144 at a predetermined distance. Further, the end edges of the lateral radiation fins 144 and the opposite ends of the middle radiation fins 142 that protrude over the opposite ends of the lateral radiation fins 144 define four installation spaces 145 in four corners of the radiation fin set 13. Further, each end of each of the middle radiation fins 142 that protrudes over the respective one ends of the lateral radiation fins 144 defines a bearing portion 143 between one respective pair of installation spaces 145 at one of two opposite sides of the radiation fin set 13.

The two retaining frames 15 are elongated frame bars, each comprising a holding-down segment 151 on the middle and a mounting segment 152 extended from each of two opposite ends of the holding-down segment 151 vertically downwards and then horizontally outwards. The holding-down segment 151 of each retaining frame 15 is pressed on a top surface of one respective bearing portion 143 of each lateral radiation fin 144, enabling each mounting segment 152 to be positioned in one respective installation space 145.

The screws 17 are respectively mounted in the mounting segments 152 of the retaining frames 15. In this embodiment, these screws 17 are spring-loaded screws.

Further, the heat spreader 11 has four corners thereof kept from interfering in the installation spaces 145.

In this first embodiment of the present invention, the heat spreader 11 has a gap 111 located in each of four corners thereof. After bonded to the bottom surface of the radiation fin set 13, the heat spreader 11 covers the middle radiation fins 142 and the lateral radiation fins 144 with the gaps 111 respectively spatially overlapped with the installation spaces 145.

After illustration of the structural details of the first embodiment of the present invention, the application of this first embodiment is outlined hereinafter.

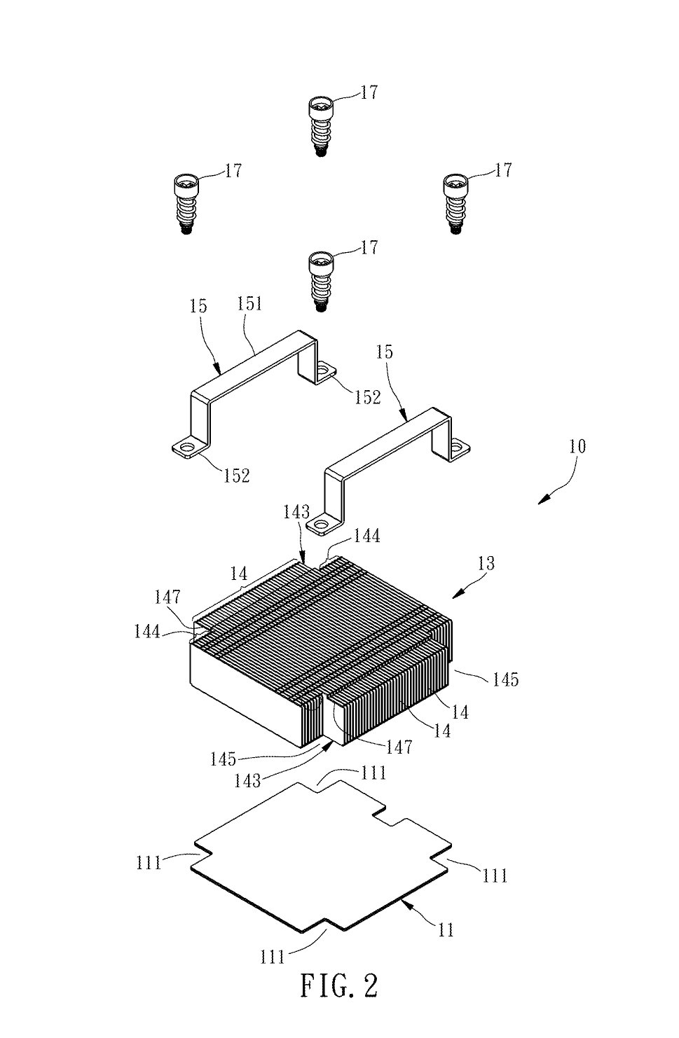

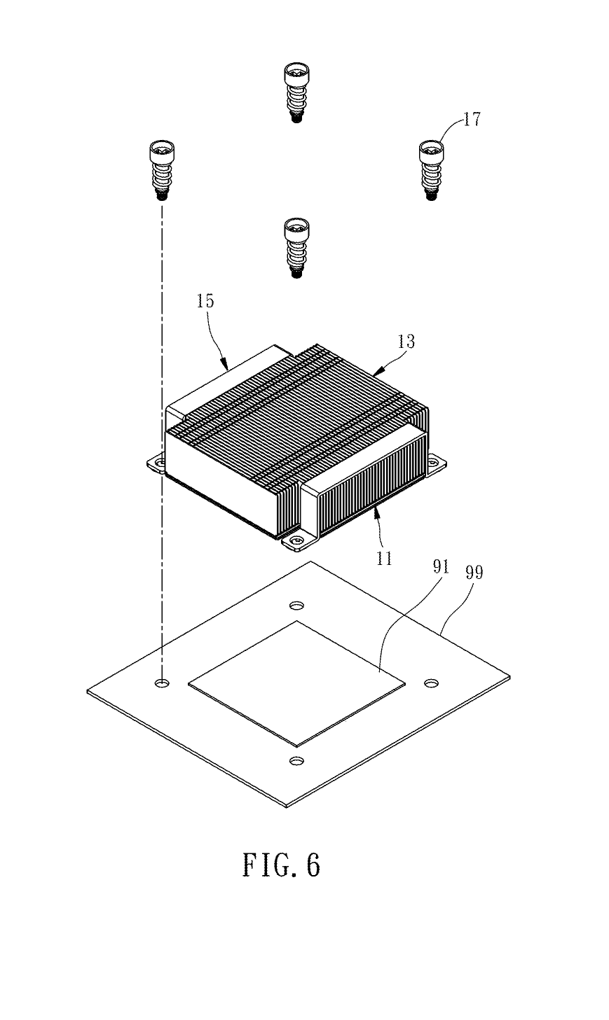

Referring to FIG. 2 and FIG. 6, mount the heat spreader 11 of the heat spreader-based heat sink module on a heat source 91 that has been mounted on a plate member (for example, circuit board) 99. In installation, bond the heat spreader 11 to the heat source 91 either directly or with a thermal compound. Using a thermal compound can eliminate the problem of uneven surface and increase the contact surface area, enhancing the heat dissipation performance. Thereafter, fasten the screws 17 to the plate member 99 to fixedly secure the retaining frames 15 to the plate member 99. At this time, the holding-down segments 151 of the retaining frames 15 are respectively pressed on the bearing portions 143 of the radiation fin set 13 to hold down the radiation fin set 13 on the heat spreader 11, thereby holding down the heat spreader 11 on the heat source 91. Using spring-loaded screws for the screws 17 can provide accurate pressure, so that the locking force imparted by the screws 17 to the two retaining frames 15 can be the same or approximately the same, ensuring that the radiation fin set 13 holds down the heat spreader 11 steadily.

In application, heat energy generated by the heat source 91 is spread through the heat spreader 11, and then transferred to the radiation fin set 13 for quick dissipation. The structure of the first embodiment of the present invention eliminates the use of a holder frame or panel frame as seen in the prior art designs, and uses a holding down technique to hold down the radiation fin set 13 on the heat spreader 11, providing the characteristics of simple structure and excellent heat dissipation performance.

In this first embodiment, each bearing portion 143 defines a step 147 at a top side thereof (see FIG. 2). The holding-down segments 151 of the retaining frames 15 are located at the steps 147 of the bearing portions 143 of the middle radiation fins 142 and kept in flush with the middle radiation fin 142 and the lateral radiation fin 144. Actually, the bearing portions 143 can be configured without the step 147, allowing the holding-down segments 151 of the retaining frames 15 to hold down radiation fin set 13 on the heat spreader 11 positively. Because this alternate form is easy to understand, it is not necessary to provide further drawings and illustrations.

Further, in this first embodiment of the present invention, the bottom surfaces of the mounting segments 152 are disposed above the elevation of the bottom surface of the heat spreader 11 (see FIG. 5). Thus, fastening up the screws 17, the mounting segments 152 can accurately receive the locking force of the screws 17, achieving the expected holding down effect.

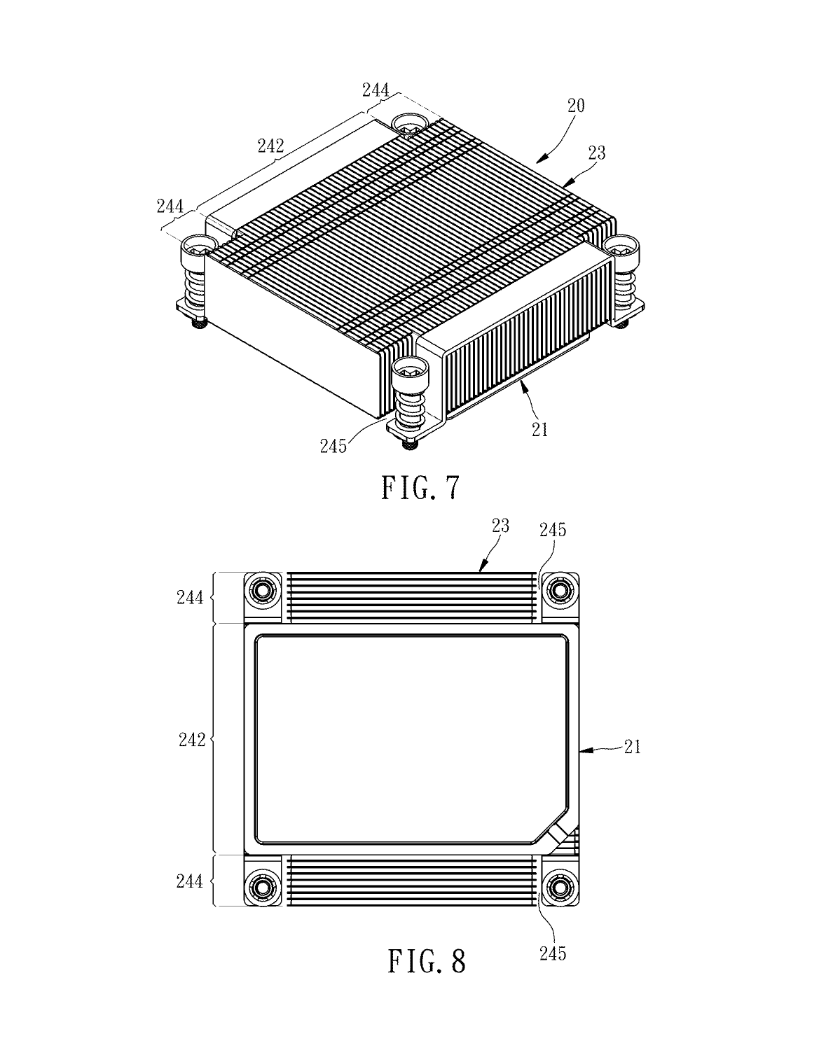

Referring to FIGS. 7 and 8, a heat spreader-based heat sink module 20 in accordance with a second embodiment of the present invention is shown. This second embodiment is substantially similar to the aforesaid first embodiment with the exceptions as explained hereinafter.

The heat spreader 21 has no gap in the four corners thereof. Substantially, the heat spreader 21 is a rectangular panel member. After the heat spreader 21 is bonded to the bottom surface of the radiation fin set 23, the heat spreader 21 covers the middle radiation fins 242 and kept beyond the bottom side of the lateral radiation fins 244. Thus, only the middle radiation fins 242 are bonded to the heat spreader 21 while the bottom side of the lateral radiation fins 244 is kept beyond the heat spreader 21 in a suspended manner.

The architecture of this second embodiment can keep the four corners of the heat spreader 21 from interfering in the installation spaces 245. Further, because it is not necessary to maintain a gap in each of the four corners of the heat spreader 21 during the fabrication, the fabrication of the heat spreader 21 is simplified.

The other structure details of this second embodiment and the effects this second embodiment to be achieved are same as the aforesaid first embodiment, therefore, no further detailed description in this regard will not be necessary.

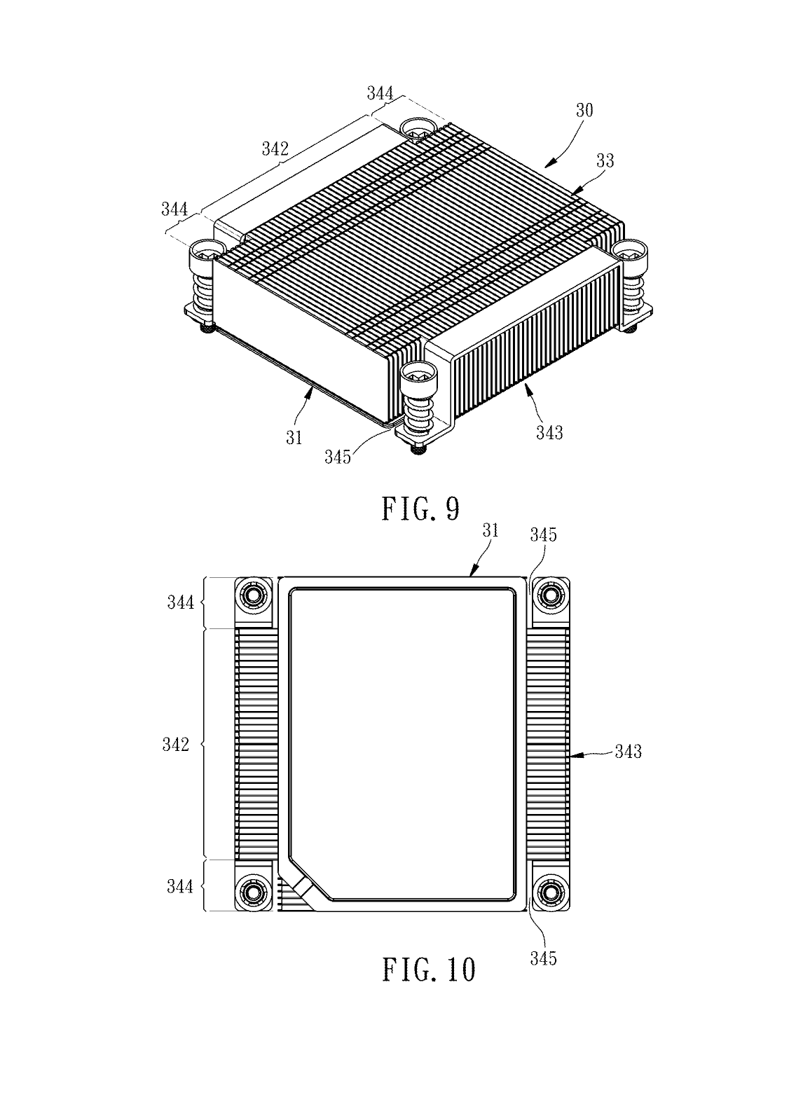

Referring to FIGS. 9 and 10, a heat spreader-based heat sink module 30 in accordance with a third embodiment of the present invention is shown. This third embodiment is substantially similar to the aforesaid first embodiment with the exceptions as explained hereinafter.

The heat spreader 31 has no gap in the four corners thereof. Substantially, the heat spreader 31 is a rectangular panel member. After the heat spreader 31 is bonded to the bottom surface of the radiation fin set 33, the heat spreader 31 covers a part of the middle radiation fins 342 and the lateral radiation fins 344 and is kept beyond the bottom side of the bearing portions 343 of the middle radiation fins 342. Thus, only a part of the middle radiation fins 342 and the lateral radiation fins 344 are bonded to the heat spreader 31 while the bottom side of the bearing portions 343 of the middle radiation fins 342 is kept beyond the heat spreader 31 in a suspended manner.

The architecture of this third embodiment can keep the four corners of the heat spreader 31 from interfering in the installation spaces 345. Further, because it is not necessary to maintain a gap in each of the four corners of the heat spreader 31 during the fabrication, the fabrication of the heat spreader 31 is simplified.

The other structure details of this third embodiment and the effects this third embodiment to be achieved are same as the aforesaid first embodiment, therefore, no further detailed description in this regard will not be necessary.

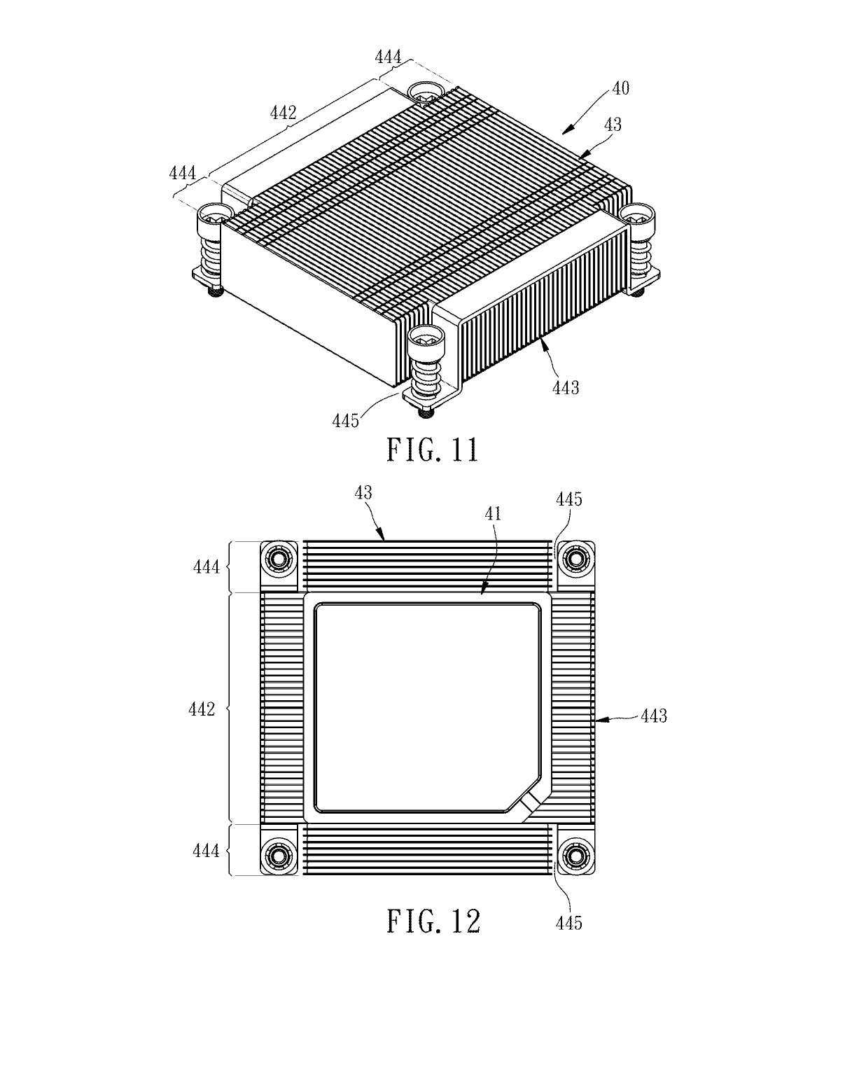

Referring to FIGS. 11 and 12, a heat spreader-based heat sink module 40 in accordance with a fourth embodiment of the present invention is shown. This fourth embodiment is substantially similar to the aforesaid first embodiment with the exceptions as explained hereinafter.

The heat spreader 41 has no gap in the four corners thereof. Substantially, the heat spreader 41 is a rectangular panel member. After the heat spreader 41 is bonded to the bottom surface of the radiation fin set 43, the heat spreader 41 covers a part of the middle radiation fins 442 and is kept beyond the bottom side of the bearing portions 443 of the middle radiation fins 442 and the bottom side of the lateral radiation fins 444. Thus, only a part of the middle radiation fins 442 and the lateral radiation fins 444 are bonded to the heat spreader 41 while the bottom side of the bearing portions 443 of the middle radiation fins 442 and the bottom side of the lateral radiation fins 444 are kept beyond the heat spreader 41 in a suspended manner.

The architecture of this fourth embodiment can keep the four corners of the heat spreader 41 from interfering in the installation spaces 445. Further, because it is not necessary to maintain a gap in each of the four corners of the heat spreader 41 during the fabrication, the fabrication of the heat spreader 41 is simplified.

The other structure details of this fourth embodiment and the effects this fourth embodiment to be achieved are same as the aforesaid first embodiment, therefore, no further detailed description in this regard will not be necessary.

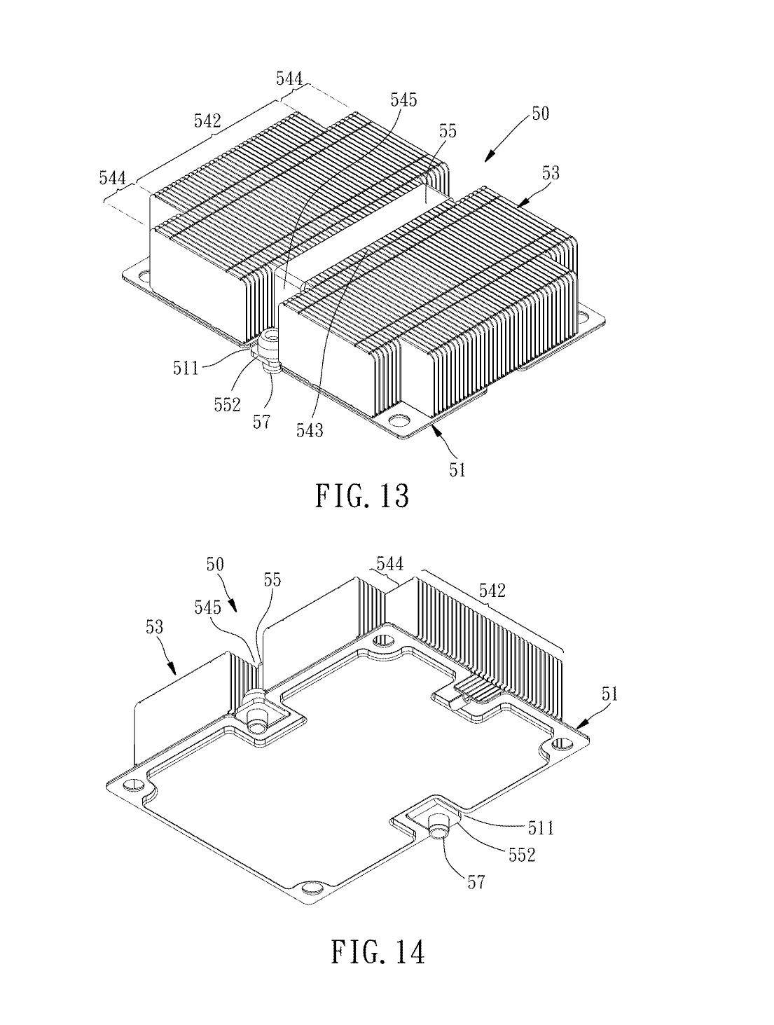

Referring to FIGS. 13 and 14, a heat spreader-based heat sink module 50 in accordance with a fifth embodiment of the present invention is shown. This fifth embodiment is substantially similar to the aforesaid first embodiment with the exceptions as explained hereinafter.

In this fifth embodiment, each of the lateral radiation fins 544 that are disposed at two opposite lateral sides relative to the middle radiation fins 542 is disconnected a predetermined distance from the middle so that the disconnected edges of the lateral radiation fins 544 and the middle radiation fins 542 define two installation spaces 545 in two opposite lateral sides of the radiation fin set 53 on the middle, thus, the bearing portions 543 of the middle radiation fin 542 defined between the two installation spaces 545 are located on the middle of the radiation fin set 53; the heat spreader 51 defines a gap 511 in each of two opposite lateral sides thereof on the middle. After the heat spreader 51 is bonded to the bottom surface of the radiation fin set 53, the gaps 511 are respectively and spatially overlapped with the respective installation spaces 545.

In this fifth embodiment of the present invention, only one retaining frame 55 is used; the two opposite mounting segments 552 of the retaining frame 55 are respectively set in the installation spaces 545; screws 57 are respectively mounted in the mounting segments 552 for fastening.

The architecture of this fifth embodiment can keep the gaps 511 of the heat spreader 51 from interfering in the installation spaces 545, facilitating installation.

The other structure details of this fifth embodiment and the effects this fifth embodiment to be achieved are same as the aforesaid first embodiment, therefore, no further detailed description in this regard will not be necessary.

What is claimed is:

1. A heat spreader-based heat sink module, comprising:
a heat spreader;
a radiation fin set consisted of a plurality of elongated radiation fins, each said radiation fin comprising an extension strip extended from each of two opposite long sides thereof, said radiation fins being arranged in parallel and joined to one another and spaced from one another at a predetermined distance by means of the extension strips thereof, the extension strips at one same long side of said radiation fins of said radiation fin set constituting a flat bottom surface and bonded with a top surface of said heat spreader;
wherein:
the said radiation fins located on a middle part of said radiation fin set are defined as middle radiation fins, and the other said radiation fins located on two opposite lateral sides of said radiation fin set are defined as lateral radiation fins; said lateral radiation fins are relatively shorter than said middle radiation fins; said lateral radiation fins have end edges thereof defining with said middle radiation fins at least two installation spaces, said at least two installation spaces being disposed at the two opposite lateral sides of said radiation fin set; each end of each of said middle radiation fins that protrudes over the respective one ends of said lateral radiation fins defines a bearing portion between one respective pair of said installation spaces at one of two opposite sides of said radiation fin set;
the heat spreader-based heat sink module further comprises: at least one retaining frame made in the shape of an elongated frame bar, each said retaining frame comprising a holding-down segment on the middle and two mounting segments respectively extended from two opposite ends of said holding-down segment vertically downwards and then horizontally outwards, said holding-down segment of each said retaining frame being pressed on a top surface of one respective said bearing portion of each said middle radiation fin, said mounting segments of said at least one retaining frame being positioned in said installation spaces; and at least two screws mounted in said mounting segments of said at least one retaining frame; wherein said heat spreader is kept beyond said installation spaces.

2. The heat spreader-based heat sink module as claimed in claim 1, wherein said middle radiation fins have two opposite ends thereof respectively protruding over respective two opposite ends of said lateral radiation fins at a predetermined distance; the opposite ends of said lateral radiation fins and the opposite ends of said middle radiation fins that protrude over the opposite ends of said lateral radiation fins define four said installation spaces in four corners of said radiation fin set; each end of each of said middle radiation fins that protrudes over the respective one ends of said lateral radiation fins defines one said bearing portion between one respective pair of said installation spaces at one of two opposite sides of said radiation fin set; said heat spreader defines a gap in each of four corners thereof; after bonding of said heat spreader with the bottom surface of said radiation fin set, said heat spreader covers said middle radiation fins and said lateral radiation fin and said gaps of said heat spreader are respectively spatially overlapped with said installation space

3. The heat spreader-based heat sink module as claimed in claim 1, wherein after bonding of said heat spreader with the bottom surface of said radiation fin set, said heat spreader covers said middle radiation fins and is kept away from a bottom side of said lateral radiation fins.

4. The heat spreader-based heat sink module as claimed in claim 1, wherein after bonding of said heat spreader with the bottom surface of said radiation fin set, said heat spreader covers a part of said middle radiation fins and said lateral radiation fins, and is kept away from a bottom side of said bearing portions of said middle radiation fins.

5. The heat spreader-based heat sink module as claimed in claim 1, wherein after bonding of said heat spreader with the bottom surface of said radiation fin set, said heat spreader covers a part of said middle radiation fins and is kept away from a bottom side of said lateral radiation fins and a bottom side of said bearing portions of said middle radiation fins.

6. The heat spreader-based heat sink module as claimed in claim 1, wherein said bearing portion of each said middle radiation fin defines a step in a top side thereof; said holding-down segment of each said retaining frame is located at said step of said bearing portion of each said middle radiation fin so that said holding-down segment of each said retaining frame is kept in flush with said middle radiation fins and said lateral radiation fins.

7. The heat spreader-based heat sink module as claimed in claim 1, wherein each said mounting segment has a bottom side thereof disposed above the elevation of a bottom surface of said heat spreader.

8. The heat spreader-based heat sink module as claimed in claim 1, wherein said screws are spring-loaded screws.

9. The heat spreader-based heat sink module as claimed in claim 1, further comprising a thermal compound bonded between the bottom surface of said radiation fin set and the top surface of said heat spreader.

10. The heat spreader-based heat sink module as claimed in claim 1, wherein each of said lateral radiation fins that are disposed at two opposite lateral sides relative to said middle radiation fins is disconnected a predetermined distance from the middle so that disconnected edges of said lateral radiation fins and said middle radiation fins define two installation spaces in two opposite lateral sides of said radiation fin set on the middle; said heat spreader defines one said gap in each of two opposite lateral sides thereof on the middle; after bonding of said heat spreader with the bottom surface of said radiation fin set, said gaps are respectively and spatially overlapped with the respective said installation spaces.
